(19) United States
(12) Patent Application Publication
(10) Pub. No.: US 2005/0024926 A1
(43) Pub. Date: Feb. 3, 2005

(54) Deskewing data in a buffer

(76) Inventors: James A. Mitchell, Chandler, AZ (US); Ali S. Oztaskin, Beaverton, OR (US)

Correspondence Address: Timothy N. Trop;TROP, PRUNER & HU, P.C., STE 100, 8554 KATY FWY, HOUSTON, TX, 77024-1841, US

(21) Appl. No.: 10/633,135

(22) Filed: Jul. 31, 2003

(51) Int. Cl. G11C 11/00

(52) U.S. Cl. 365/154

(57) ABSTRACT

In one embodiment, the present invention includes a method to receive a data sequence in a receiver having a plurality of lanes, detect a predetermined character in the data sequence in a first lane, and track a time period until the plurality of lanes detects the predetermined character.

### BACKGROUND

The present invention relates to buffering data and more particularly to buffering data that may be skewed.

In certain communication protocols, data in different physical channels may leave a transmitter at the same time and be received by a receiver at different times, causing misalignment or skew of the data. Although data may leave the transmitter at the same time, due to routing length differences, driver strengths and temperature, data on the different lanes can be received at a destination at different times, causing misalignment.

In the InfiniBand™ protocol (as set forth in the InfiniBand™ Architecture Specification Release 1.1, Nov. 6, 2002), when higher bandwidths are desired, multiple X1 lanes are combined to increase the rate at which data packets are sent. Such multiple lane modes may include an X4 mode and an X12 mode. When data is sent in X4 mode, four X1 lanes are combined and data is sent byte striped across the 4 lanes.

As an example of byte striping, a first byte may be sent on a first lane, a second byte sent on a second lane, a third byte sent on a third lane, a fourth byte sent on a fourth lane, a fifth byte sent on the first lane, and so on. In an X4 mode, data may be skewed in that data in lane 2 or lane 3, for example, is received before data from lane 0. Thus a need exists to deskew data that is misaligned during communication.

### BRIEF DESCRIPTION OF THE DRAWINGS

FIG. 1 is a block diagram of a deskew block in accordance with one embodiment of the present invention.

FIG. 2 is a state diagram of a lane zero deskew state machine in accordance with one embodiment of the present invention.

FIG. 3 is a state diagram of a lane one, two or three deskew state machine in accordance with one embodiment of the present invention.

FIG. 4 is a block diagram of a system in accordance with one embodiment of the present invention.

### DETAILED DESCRIPTION

In various embodiments, data from multiple channels may be deskewed to realign the data so that a downstream receiver may receive correctly aligned bytes from channel to channel. In one embodiment, such deskewing may be performed by a deskew logic block. While discussed herein with respect to an embodiment for the InfiniBand™ protocol, other embodiments may be used in connection with other protocols such as a Peripheral Component Interconnect (PCI) Express architecture, PCI-SIG PCI Express Base Specification Rev. 1.0 (published Jul. 22, 2000) or another such protocol. Embodiments may be suitable for other serial protocols having multiple lanes, and other point-to-point protocols.

Deskewing in accordance with one embodiment of the present invention may be performed to realign individual lane data such that a downstream receiver may have correctly aligned bytes from lane to lane. In certain embodiments, skew of up to six symbol times between four lanes in an X4 mode of an InfiniBand™ system may be removed. Embodiments may be used for both X1 mode and X4 mode transmissions, although the scope of the present invention is not limited in this respect.

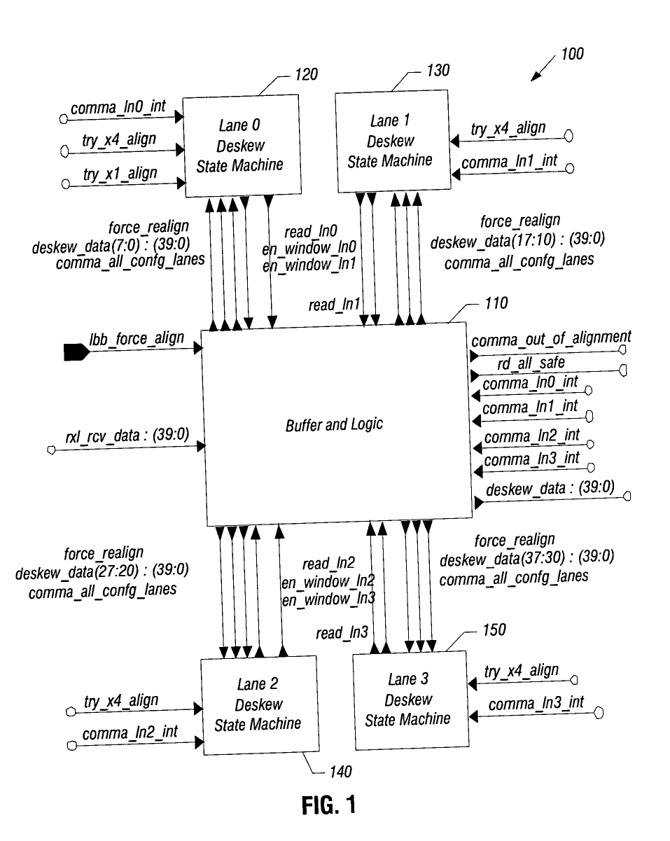

Referring now to FIG. 1, shown is a block diagram of a lane deskew block in accordance with one embodiment of the present invention. In one embodiment the lane deskew block may be present in a host channel adapter (HCA). As shown in FIG. 1, block 100 includes a buffer and logic 110, lane zero deskew state machine 120, lane one deskew state machine 130, lane two deskew state machine 140, and lane three deskew state machine 150. While the embodiment shown in FIG. 1 includes deskew state machines for four lanes, it is to be understood that in other embodiments, more or fewer state machines may be present, depending upon a desired communication protocol, mode, or other factors.

As shown in FIG. 1, each of deskew state machines 120, 130, 140, and 150 may be coupled to buffer and logic 110. In one embodiment, each deskew state machine may include logic to perform deskew operations as described herein. More specifically, each deskew state machine may be coupled to transfer data, control, and status signals between the state machine and buffer and logic 110 (reference numeral 110 is used herein to refer to both a buffer and logic). Buffer and logic 110 may also be coupled to receive data from a link layer, such as a transmitter or other source providing serial data. For example, in one embodiment, buffer 110 may receive manipulated parallel data from a serial data interface such as 2.5 Gigabits per second (Gbps) data from a switch, a HCA target channel adapter (TCA) or other device to which it is coupled. As shown in FIG. 1, such data may be received over a rxl_rcv_data line. Buffer and logic 110 may also be coupled to provide deskewed data to a downstream unit such as a transaction layer via a deskew_data output line.

Referring to FIG. 1, buffer and logic 110 provides signals to each of the lane deskew state machines, as will be discussed in more detail below. Specifically, each lane receives data (e.g., deskew_data) and control signals (e.g., force_realign and comma_all_config_lanes). In turn, each of the lane deskew state machines provides a read (read_lane) signal and an enable (en_window_lane) signal back to buffer and logic 110. Other control inputs into the deskew state machines include a try_X 4_align signal and a comma_lane_interrupt signal. Also, lane 0 deskew state machine 120 receives a try_X1_align signal.

Similarly, buffer and logic 110 receives comma_lane_interrupt signals for each of the lanes. Also, buffer and logic 110 receives a LBB_force_align signal, which may be controlled by software to start a deskew operation.

In one embodiment, buffer and logic 110 may include four register files and associated multiplexers (not shown in FIG. 1), control and read/write logic. The register files may be used to deskew the lanes. In one embodiment, each of the register files may be 10 bits wide and 8 units deep. More so, the register files may be structured as first-in-first out (FIFO) registers, so that incoming data moves up through the register files such that the first data packet received is the first packet to exit the top of the register file. While in the embodiment of FIG. 1, there is one register file for each of lanes 0, 1, 2 and 3, it is to be understood that in other embodiments, more or fewer register files may be present, as dictated by a particular mode of operation.

In one embodiment, each of the deskew state machines may use a training sequence one ordered-set (TS1) and a training sequence two ordered-set (TS2) to deskew the lanes. In such an embodiment, each lane deskew state machine may detect the presence of a comma character contained in the front of the training sequence. When a comma character is detected on a particular lane deskew state machine, a counter which may be located, for example, in logic 110, may be initiated to track the number of cycles from the detection of the comma character until commas are detected on all of the lanes.

In this embodiment, once commas are detected on all four lanes, reading of all the data is allowed. If the count becomes greater than six for any particular lane and all of the lanes have not yet detected commas, the deskew operation may be invalidated and begun again.

While discussed in the above embodiment as being activated by a comma character, embodiments of the present invention are not so limited. For example, any predetermined code (i.e., any number, character, symbol, or other identifier) may be used to begin a count of cycles. Further, in other embodiments such a predetermined code need not be part of a training sequence, and may instead be part of any desired data packet.

In the embodiment shown in FIG. 1, data may be written into each of the four register files on every cycle. Thus even prior to being deskewed, data may be stored in the register files. However, SKIP (SKP) characters may be dropped prior to writing into the register files by not advancing a write pointer within logic 110. In such manner, SKP characters do not propagate through the FIFO's of the register files. During operation in an X1 mode, data may bypass the register files entirely and pass out of buffer 110.

In one embodiment after reset, all lanes may be popped on every cycle. This may be done because during a first portion of link training (i.e., polling and configure_debounce), data is examined to find a TS1 sequence on any lane. In such an embodiment, read and write pointers in logic 110 may be offset by 2, so that initial read/write pointers are not equal.

After an initial portion of a link training state machine occurs, a deskew operation may be performed if an X4 mode or auto X4 mode is present. During this operation, each lane may be popped independently until a comma is seen on that lane. Then a stop and wait state may be entered until a comma character is seen on all lanes. In one embodiment, the first lane to detect a comma may start a counter in logic 110. If the counter reaches a predetermined number of cycles without being reset, the deskewing operation may be repeated, in certain embodiments. For example, in one embodiment, if the counter reaches a count of six, meaning six symbols have passed, the deskew operation may be deemed to be unsuccessful and may be begun again.

Alternately, if all lanes see a comma before the counter reaches the predetermined count, then a valid signal may be asserted, indicating that the link has been successfully deskewed. In the embodiment of FIG. 1, a comma_all_config_lanes signal may be asserted by logic 110 to indicate that the link is deskewed. Instead of a counter, in certain embodiments a timer may be used and may be set to expire if a predetermined number of cycles passes without each lane checking in.

Once the link is deskewed, it may be monitored to confirm that it remains deskewed. For example, in one embodiment the link may be monitored by confirming that when a comma character is seen, it is seen on all lanes simultaneously. If not, the link has become skewed and a deskew operation may be performed again.

In an embodiment implementing an InfiniBand™ protocol, since SKP characters may not be written into buffer 110, it may become empty after a period of time. To prevent the emptying of buffer 110, read operations may be qualified, in certain embodiments. For example, in one embodiment, a buffer depth count may be set at a predetermined value for all lanes before the lanes can be read. For example in one embodiment, the buffer depth count may be set to be greater than or equal to two. In such an embodiment, if SKP characters or other situations cause a buffer depth to be two or less, data may be stalled until such a depth is reached. In certain embodiments, as a safety measure all register files may be written to assert errors if the buffers are either underflowed or overflowed.

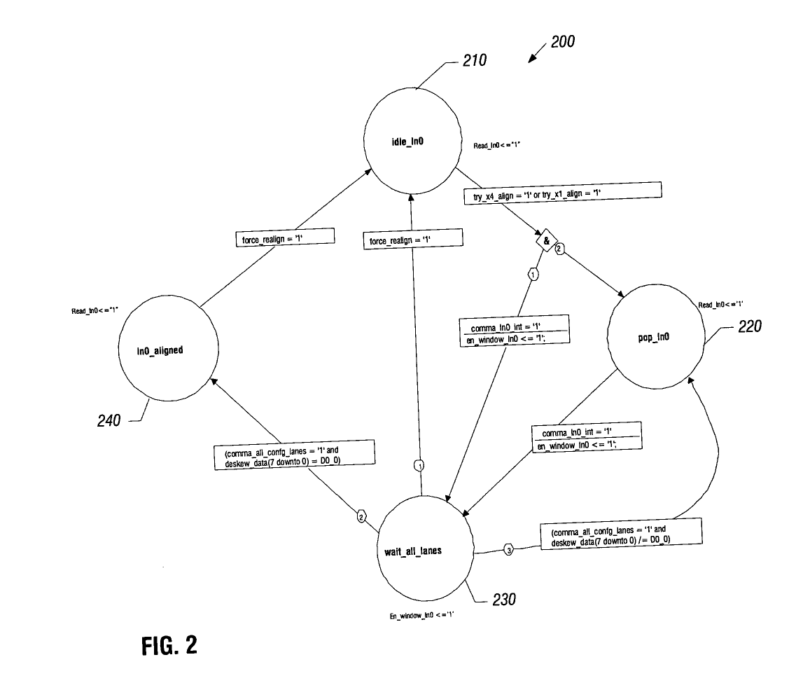

Referring now to FIG. 2, shown is a state diagram of a lane 0 deskew state machine in accordance with one embodiment of the present invention. As shown in FIG. 2, the state diagram may be for a lane 0 deskew state machine that can operate in both X4 mode and X1 mode. The lane 0 deskew state machine may be responsible for controlling the deskewing operation, as discussed above.

As shown in FIG. 2, at state 210 of state diagram 200, lane zero is in an idle state (idle_ln0) in which data is read from buffer 110 until a TS1 sequence is detected on any lane. Such an idle status may occur on a reset condition or on power up, for example. As shown in FIG. 1, the deskew state machine may output a read_ln0 signal to logic 110.

After reset, the deskew state machine may try to align incoming data. For example either a try_X4_align or a try_X1_align signal may be provided to the lane 0 deskew state machine 120. When a first TS1 sequence is detected on any lane, data may be popped until a comma character is seen in this lane, as represented by state 220 (pop_ln0). If a comma symbol is already present, control may directly pass to state 230 (wait_all_lanes). When a comma is detected in lane 0, control may pass to state 230 in which the deskew state machine waits until all lanes detect a comma. Also, a comma_ln0_interrupt signal and an en_window_ln0 signal may be asserted to indicate that a comma is present on lane 0 and to enable the counter within logic 110. For example, a counter or timer may be used to determine whether commas are detected in each lane prior to meeting a predetermined count or expiration of a predetermined time period. If a timeout occurs (or under software control), a signal (force_realign) may be asserted to send the deskew state machine back to state 210, to begin a deskew operation again.

If a comma is detected in all configured lanes before a timeout occurs, the link is thus aligned, as represented by aligned state 240 (ln0_aligned). Also, a comma_all_config_lanes signal may be asserted to the deskew state machines, and deskew data for lane 0 (i.e., deskew_data (7:0) ) may be sent to lane 0 deskew state machine 120. If after such alignment the link falls into misalignment, the force_realign signal may be activated to cause the state machine to return to state 210 and begin the deskew operation again.

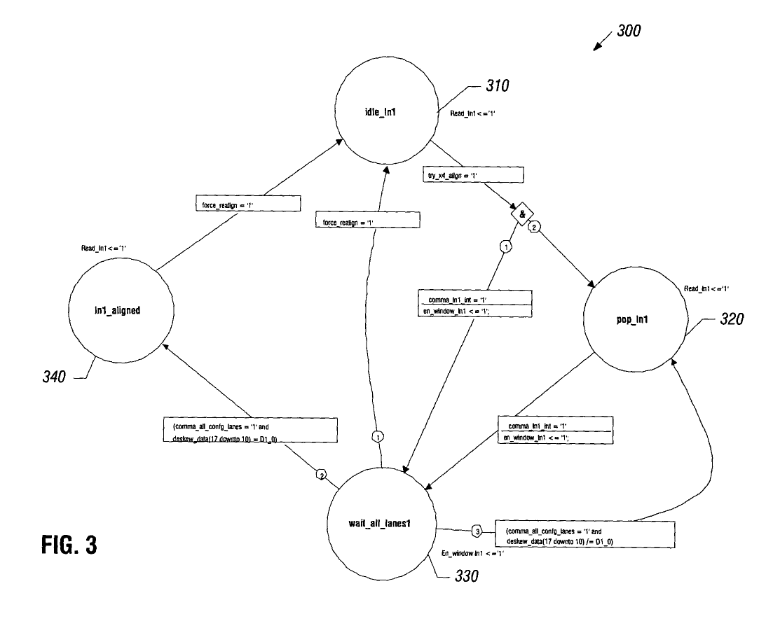

Referring now to FIG. 3, shown is a state diagram of a deskew state machine for any of lanes 1, 2 and 3 in accordance with one embodiment of the present invention. As shown in FIG. 3, state diagram 300 may represent any one of lanes one, two or three in an X4 mode of operation. While reference in FIG. 3 and this discussion may be made with regard to lane 1, both this discussion and FIG. 3 may be applicable to each of lanes one, two and three in an X4 mode of operation.

As shown in FIG. 3, at state 310 (idle_{—ln}1), lane 1 is in an idle mode in which data is read until a TS1 sequence is detected on any of the lanes. At such time, state 320 (pop_{—ln}1) is entered and data is popped from lane 1 until a comma is seen on lane 1. When a comma is seen on lane 1, a wait state is entered at 330 (wait_all_lanes1) where it is determined how many cycles occur before commas are seen on all configured lanes. If a timeout occurs or under software control, the force_realign signal may be asserted to send the deskew state machine back to state 310 to begin a deskew operation again. If commas are seen on all configured lanes before a timer timeout occurs, an aligned state 340 (ln1_aligned) is entered. If the link falls out of alignment, the force_realign signal is activated, causing the state machine to return to state 310.

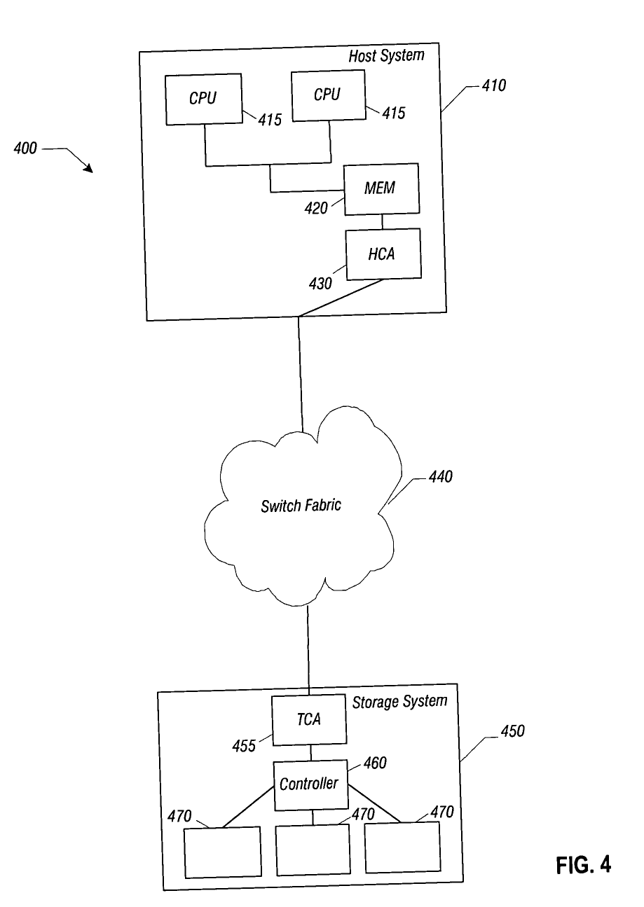

Referring now to FIG. 4, shown is a block diagram of a system area network (SAN) in accordance with one embodiment of the present invention. As shown in FIG. 4, SAN 400 includes a host system 410, switch fabric 440 and a storage system 450. While shown as including only a single host system and a single storage system, it is to be understood that in other embodiments multiple host systems and multiple input/output (I/O) systems such as storage subsystems, remote servers and the like may be coupled to switch fabric 440.

As shown in FIG. 4, host system 410 includes a plurality of central processing units (CPU) 415, each of which is coupled to a memory 420. Memory 420 is coupled to a host channel adapter (HCA) 430. Alternately, memory 420 may be a memory controller hub or similar bridge device to which a HCA is coupled. In one embodiment, HCA 430 may include deskew block 100 of FIG. 1. As shown in FIG. 4, HCA 430 may be coupled to switch fabric 440.

Switch fabric 440 may include, in various embodiments switches, routers or other connecting devices. In the embodiment of FIG. 4, switch fabric 440 may be an InfiniBand™ fabric, although other fabrics may be possible in other embodiments.

As shown in FIG. 4, storage system 450 may include a target channel adapter (TCA) 455. TCA 455 may include a deskew block 100 as discussed above with regard to FIG. 1, in one embodiment. As shown in FIG. 4, TCA 455 may be coupled to a controller 460 to which is coupled a plurality of storage devices 470. In one embodiment, storage devices 470 may be a redundant array of independent disks (RAID) or other storage mechanisms. It is to be understood that the SAN 400 of FIG. 4 is one example system with which embodiments of the present invention may be used, and various other systems may incorporate embodiments of the present invention.

Embodiments may be implemented in a computer program that may be stored on a storage medium having instructions to program a system to perform the embodiments. The storage medium may include, but is not limited to, any type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic RAMs and static RAMs, erasable programmable read-only memories (EPROMs), electrically erasable programmable read-only memories (EEPROMs), flash memories, magnetic or optical cards, or any type of media suitable for storing electronic instructions. Other embodiments may be implemented as software modules executed by a programmable control device, such as a processor or a custom-designed state machine.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
receiving a data sequence in a receiver having a plurality of lanes;
detecting a predetermined character in the data sequence in a first lane; and
tracking a time period until the predetermined character is detected in the plurality of lanes.

2. The method of claim 1, further comprising resetting the receiver if a predetermined number of cycles is exceeded before the predetermined character is detected in the plurality of lanes.

3. The method of claim 1, further comprising realigning the data sequence based on when the predetermined character is detected in each of the plurality of lanes.

4. The method of claim 3, further comprising transmitting the realigned data sequence from the receiver after the predetermined character is detected in the plurality of lanes.

5. The method of claim 3, further comprising determining whether the predetermined character is received simultaneously on the plurality of lanes.

6. The method of claim 1, wherein the data sequence comprises a training sequence.

7. The method of claim 1, wherein the data sequence is byte striped.

8. A method comprising:
receiving data packets on a plurality of channels of a receiver;
determining whether the data packets are misaligned while the data packets are maintained in buffers corresponding to the plurality of channels; and
aligning the data packets if the data packets are misaligned.

9. The method of claim 8, wherein determining whether the data packets are misaligned comprises analyzing whether a predetermined value is received on each of the plurality of channels within a first time period.

10. The method of claim 8, further comprising transmitting the data packets in an aligned manner.

11. The method of claim 10, further comprising holding the data packets until each of the buffers has a predefined depth.

12. The method of claim 8, further comprising realigning the data packets if the data packets become misaligned.

13. The method of claim 8, wherein the data packets are byte striped.

14. An apparatus comprising:
buffers to store data packets from a plurality of channels; and
a state machine coupled to the buffers to deskew the data packets while the data packets are stored in the buffers.

15. The apparatus of claim 14, wherein the state machine is adapted to hold the data packets in the buffers until a predetermined character is present in each of the buffers.

16. The apparatus of claim 15, further comprising a counter to count cycles occurring after receipt of a first data packet having the predetermined character.

17. The apparatus of claim 14, further comprising a plurality of state machines, each corresponding to one of the plurality of channels.

18. The apparatus of claim 14, wherein the data packets comprise InfiniBand data packets.

19. An article comprising a machine-readable storage medium containing instructions that if executed enable a system to:
receive a data sequence in a receiver having a plurality of lanes;
detect a predetermined character in the data sequence in a first lane; and
track a time period until the predetermined character is detected in the plurality of lanes.

20. The article of claim 19, further comprising instructions that if executed enable the system to reset the receiver if a predetermined number of cycles is exceeded before the predetermined character is detected in the plurality of lanes.

21. The article of claim 19, further comprising instructions that if executed enable the system to determine whether the data sequence is misaligned while the data sequence is maintained in buffers corresponding to the plurality of lanes.

22. A system comprising:
a switch fabric;
a plurality of buffers coupled to the switch fabric to receive data packets from a plurality of channels; and
a state machine coupled to the plurality of buffers to deskew the data packets while the data packets are received in the plurality of buffers.

23. The system of claim 22, further comprising a host channel adapter including the plurality of buffers.

24. The system of claim 23, wherein the host channel adapter further includes a counter to count cycles occurring after receipt of a first data packet having a predetermined character.

25. The system of claim 22, wherein the switch fabric comprises an InfiniBand switch fabric.
